(19) United States
(12) Patent Application Publication
(10) Pub. No.: US 2002/0081869 A1
(43) Pub. Date: Jun. 27, 2002

(54) High density electrical connector

(76) Inventor: Russell M. Abbott, Riverside, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/938,852

(22) Filed: Aug. 23, 2001

Related U.S. Application Data
(60) Provisional application No. 60/227,855, filed on Aug. 23, 2000.

(51) Int. Cl. H05K 1/00

(52) U.S. Cl. 439/66; 439/700

(57) ABSTRACT

A device for interconnecting electrical devices employing a plurality of compressible micron scale gold-plated contacts positioned within an interposer structure such that the contacts are held in spring tension with contact pads of a printed circuit board and conductive traces of a flex cable. The flex cable contains laterally extending overlying conductive traces extending in parallel, orthogonal, radial, non-linear, or other patterns so as to provide a region of high contact density at one end of the traces and a corresponding region of lower contact density at the other end of the traces. In one version, the connector provides a vertical stack of printed circuit boards and interposers with contacts contained therein to enable vertical interconnection of the printed circuit boards while providing tolerance for various placements of the printed circuit boards within the connector stack without impairing the functioning of the circuits contained on the printed circuit boards.

### RELATED APPLICATIONS

This application claims the benefit of U.S. Provisional Application No. 60/227,855 filed Aug. 23, 2000, entitled High Density Connector and Alignment Mechanism.

### BACKGROUND OF THE INVENTION

1. Field of the Invention

This invention relates to the field of electrical connectors and, in particular to an improved connector for coupling to a printed circuit board (PCB). Specifically, this invention is a connector that couples a PCB having a plurality of closely spaced small contact leads to another less closely spaced contact area in a removable fashion.

2. Description of the Related Art

Modern electronic devices such as computers and the like typically include electronic circuitry formed in or attached to one or more printed circuit boards (PCBs). In particular, a typical PCB includes a plurality of conducting pads and a plurality of interconnecting conductive traces that extend from the pads along a planar surface of the PCB. Moreover, the typical PCB further includes a plurality of modular components, such as packaged integrated circuits (PICs) of varying complexity as well as discrete resistors, capacitors, and transistors. These modular components, typically having a plurality of conducting leads extending therefrom, are mounted to a surface of the PCB so as to electrically couple the leads of the modular components to the pads of the PCB to thereby interconnect the modular components in a desired manner.

Various methods are now relied upon to couple a PIC to a PCB. In one known method, the leads of the PIC are soldered directly to the pads of the PCB so as to permanently mount and electrically couple the PIC to the PCB. In another method, a connector having a plurality of parallel conducting pins is interposed between the PIC and the PCB so that the PIC is detachably mounted to the PCB and so that the pins interconnect the leads of the PIC to the pads of the PCB. Thus, since the leads of the PIC are aligned with the pads of the PCB in both of the aforementioned methods, the PCB must be formed so that the footprint of the contact pads of the PCB matches the footprint of the leads of the PIC.

A drawback with soldered connections is that they are permanent. PICs and other components are not typically repairable in case of failure and must typically be replaced to restore devices employing the PICs and discrete components to full function. The equipment required to remove a PIC soldered in place and to reform the solder connection with a new PIC is elaborate, expensive, and not typically available to many end uses of devices employing the solder connection. Thus, components employing a solder connection are not readily replaceable in the field. Thus, a failure in a relatively low cost discrete component or PIC can render a much more expensive printed circuit board or electronic device useless if the discrete component cannot be replaced.

Accordingly, a removable connector is often employed in electronic device designs to facilitate removable connection to the PCB(s). Current designs often call for 100 or more individual contacts and, as electronic device become increasingly more complex, there is an ever-present upward trend in contact count. In many applications, such as portable consumer electronics and space and atmospheric flight vehicles, size and weight is at a premium. In many applications, the size of the connectors is a limiting factor in decreasing the size of the device. It will be appreciated that this is also a constraint on providing increased functionality with attendant increase in contact count.

An additional design goal is to provide connector designs that are tolerant of alternative placements of PCBs. This would facilitate replacement of faulty components or upgrading with new designs by inexperienced operators or robotically. Facilitating replacement of PCBs robotically is especially desirable in spacecraft where human repair is not available or safe and where a component failure can cripple a multi-million dollar mission that may not repeatable.

From the foregoing, it can be appreciated that there is an ongoing need for a device and method for interconnecting to high density contacts in a removable manner. There is also a need for interconnecting electrical components having high contact density with other electrical components having lower contact density. There is also a need for a connector that can accommodate alternative placement of components. There is a further need for a high density connector of smaller dimensions than known designs.

### SUMMARY OF THE INVENTION

The aforementioned needs are satisfied by the invention, which in one aspect is a device for interconnecting a first electrical device having a plurality of contacts disposed on a first surface in a first pattern at a first density to a second electrical device having a plurality of contacts disposed on a second surface in a second pattern at a second density, wherein the second density is less than the first density, the device comprising a first contact support structure that includes a plurality of contact members each having a first and a second end wherein the plurality of contact members are arranged in the first pattern such that when the contact support structure is positioned adjacent the first surface of the first electrical device, the first end of the plurality of the contact members are electrically coupled to the first plurality of contacts and a lateral expansion structure having a plurality of laterally extending traces each having a first and a second expansion contact arranged at first and second ends of the laterally extending traces respectively wherein the first expansion contacts are coupled to the second ends of the plurality of contact members and wherein the second expansion contacts are arranged so as to be coupled to the plurality of contacts on the second electrical device. In certain aspects, the invention further comprises a securing mechanism that removably secures the first and second electrical devices, the contact support structure and the lateral expansion structure together.

In certain aspects, the first electrical device comprises a packaged integrated circuit and the second electrical device comprises a printed circuit board and the contact support structure comprises a planar member having a plurality of openings formed therein and wherein the plurality of contacts members comprise a plurality of compressible contacts positioned within the openings such that the first and second ends of the contact members protrude therefrom so as to make electrical contact with the plurality of contacts of the first electrical device and the first expansion contacts of the laterally extending traces of the lateral expansion structure respectively. In one aspect, the lateral expansion structure comprises a flex cable having a first area upon which the first plurality of expansion contacts are disposed and a second area upon which the second plurality of expansion contacts are disposed and wherein the flex cable includes an interposed region between the first and second surfaces where the plurality of laterally extending traces are disposed.

In a particular aspect, the invention further comprises a second contact support structure that includes a plurality of contact members each having a first and a second end wherein the plurality of contact members are arranged in the second pattern wherein the second contact support structure is interposed between the lateral expansion structure and the second electrical device such that the first end of the plurality of the contact members are electrically coupled to the second expansion contacts and the second ends of the contact members are electrically coupled to the second device. In one aspect, the first pattern comprises a spacing pitch of no more than 0.25 mm and the second pattern comprises a spacing pitch of at least 0.75 mm and in another aspect the second pattern has a pitch of at least three times the pitch of the first pattern.

In another aspect, the invention is a device for interconnecting a first contact pattern of a first density to a second contact pattern of a second density, the device comprising a contact structure having a plurality of contact members each having a first end and a second end wherein the first ends of the plurality of contact members electrically couple to the first contact pattern and wherein the plurality of contact members extend in a first direction that intersects the first surface such that the second ends of the plurality of contact members are spaced from the first plurality of contacts in the first direction and an expansion structure that has a first plurality of expansion contacts that electrically couple to the second ends of the plurality of contact members when the expansion structure is mounted to the contact structure, wherein the expansion structure further includes a plurality of laterally extending conductors each having a first end that is electrically coupled to the first plurality of expansion contacts wherein the laterally extending conductors extend in a second direction that intersects the first direction and wherein the lateral expansion structure further includes a plurality of second expansion contacts that are coupled to the second ends of the laterally extending conductors such that the plurality of second expansion contacts device the second contact pattern at a second density that is laterally spaced outward from the first contact pattern.

In yet another aspect, the invention is a device for removably interconnecting electrical devices comprising a plurality of resiliently compressible contacts, an interposer containing the plurality of contacts wherein the contacts extend from a first face of the interposer to a second face of the interposer opposite the first face of the interposer, a first electrical circuit having a plurality of circuit nodes, each node in electrical contact with one end of one of the contacts, and a flex cable comprising a plurality of laterally extending electrically conductive traces wherein one end of the electrically conductive traces is in electrical contact with a second end of the contacts and wherein the flex cable provides a region of relative high conductor density at one end of the electrically conductive traces and a corresponding region of relative low conductor density at a second end of the electrically conductive traces. In certain aspects, the conductive traces of the flex cable extend in a parallel arrangement.

A further aspect of the invention is a device for vertically interconnecting electrical components comprising a plurality of compressible contacts, an interposer containing the plurality of contacts wherein the contacts extend from a first face of the interposer to a second face of the interposer opposite the first face of the interposer, and an electrical device containing a plurality of electrical circuit components in electrical contact with one end of the contacts. In particular aspects, the invention comprises alternating layers of a plurality of interposers each containing a plurality of contacts and a plurality of electrical devices positioned in alignment with the interposers. In additional aspects, the invention includes corresponding contacts contained within the interposers are electrically continuous throughout the vertical extent of the device.

### BRIEF DESCRIPTION OF THE DRAWINGS

FIG. 1 is a perspective, exploded view of one embodiment of a high density electrical connector;

FIG. 2 is a close-up, top view of the positioning structures formed in one embodiment of the interposer of the high density electrical connector;

FIG. 3 is a side view of a contact of the high density electrical connector;

FIG. 4 is a perspective, cutaway view of one embodiment of a flex cable;

FIG. 5 is a perspective, exploded view of an alternative embodiment of a high density electrical connector system;

FIG. 6 is a perspective, exploded view of another alternative embodiment of a high density electrical connector system;

FIG. 7 is a side, section view of one embodiment of the high density electrical connector of FIG. 6; and

FIG. 8 is a top, detail schematic illustration of a first contact area of the high density electrical connector of FIG. 6.

### DETAILED DESCRIPTION OF THE PREFERRED EMBODIMENT

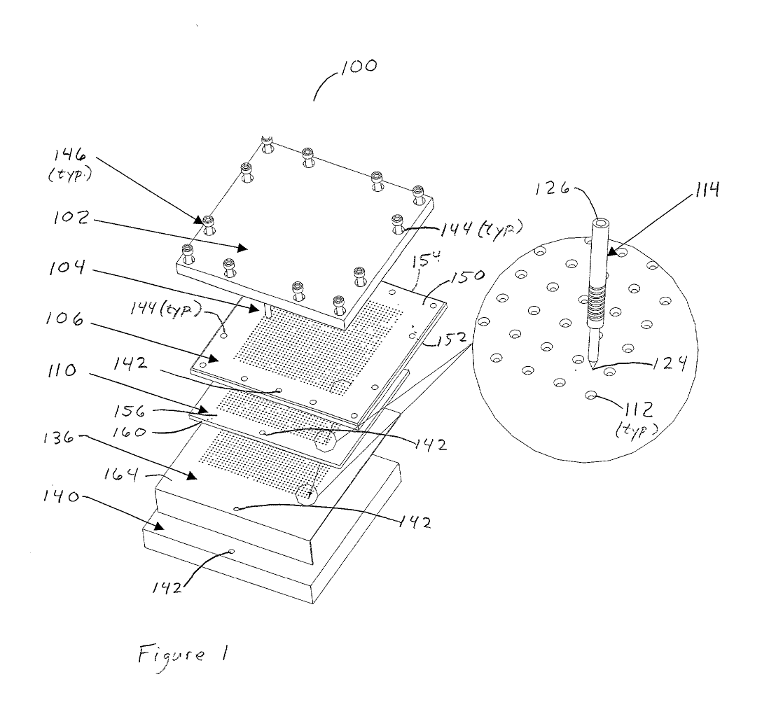

Reference will now be made to the drawings wherein like numerals refer to like parts throughout. FIG. 1 illustrates an exploded, perspective view of one embodiment of a high density electrical connector 100. The high density electrical connector 100 removably interconnects a plurality of electrical circuit elements between areas of relatively high and relatively low contact density in a manner that will be described in greater detail below. The high density electrical connector 100 comprises a stiffener cover 102. The stiffener cover 102 is generally rectangular and is made of an electrically insulative, rigid material. The stiffener cover 102 provides mechanical rigidity for the high density electrical connector 100 and provides a bearing and support structure as well as an interconnection component in a manner that will be described in greater detail below.

The high density electrical connector 100 also comprises at least two guide pins 104. The guide pins 104 are cylindrical, elongate, rigid members that are fixedly attached to a first face of the stiffener cover 102 so as to extend perpendicular to the first face of the stiffener cover 102. The guide pins 104 maintain other component parts of the high density electrical connector 100 in alignment in a manner that will be described in greater detail below.

The high density electrical connector 100 also comprises a printed circuit board 106. The printed circuit board 106 is a rectangular assembly comprising an electrically non-conductive rigid substrate with a plurality of electrically conductive traces formed therein. The printed circuit board 106 preferably also comprises a plurality of electrical circuit components (not shown) such as transistors, resistors, and capacitors interconnected with the conductive traces so as to form electrical circuits in a known manner. The printed circuit board 106 has a first face 150 and a second face 152 opposite the first face 150. In this embodiment, a plurality of contact pads 154 are disposed on the second face 152 (obscured from view in FIG. 1). The contact pads 154 are known exposed regions of the conductive traces of the printed circuit board 106 and facilitate interconnection with the circuits of the printed circuit board 106 in a manner that will be described in greater detail below.

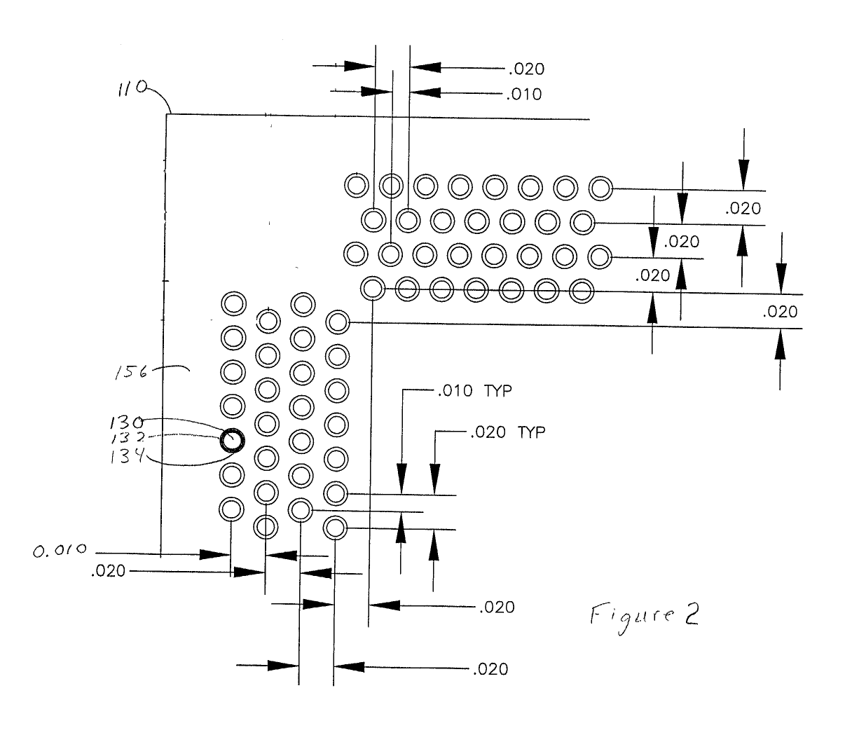

The high density electrical connector 100 also comprises an interposer 110 serving as a contact support structure. The interposer 110 is a rectangular, rigid member and is made of an electrically non-conductive material. The interposer has a first face 156 and a second face 160, opposite the first face 156. The interposer 110 is provided with a plurality of positioning structures 112 extending between the first face 156 and the second face 160 as shown in FIG. 1 and in greater detail in FIG. 2. In this embodiment, the interposer 110 comprises 1220 positioning structures 112. The positioning structures 112 enclose and position a plurality of contacts 114 in a manner that will be described in greater detail below.

The positioning structures 112, of this embodiment, comprise a plurality of through going openings 130 approximately 0.231 mm in diameter. The through going openings 130 of the positioning structures 112, in one embodiment, are advantageously formed in the interposer 110 by a #89 drill in a known manner. The positioning structures 112 further comprise a plurality of corresponding non-through going opening 132 concentric with the through going openings 130. The non-through going openings 132, of this embodiment, are approximately 0.343 mm in diameter and extend approximately 3.6 mm into the interposer 110 from the first face 156. The non-through going openings 132 of this embodiment are advantageously formed by a #80 drill in a known manner.

The non-through going openings 132 concentric with the through going openings 130 define a plurality of steps 134 as shown in FIG. 2. The steps 134 are annular surfaces parallel to the first 156 and second 160 faces of the interposer 110 and are approximately 0.343 mm O.D. and 0.231 mm I.D.

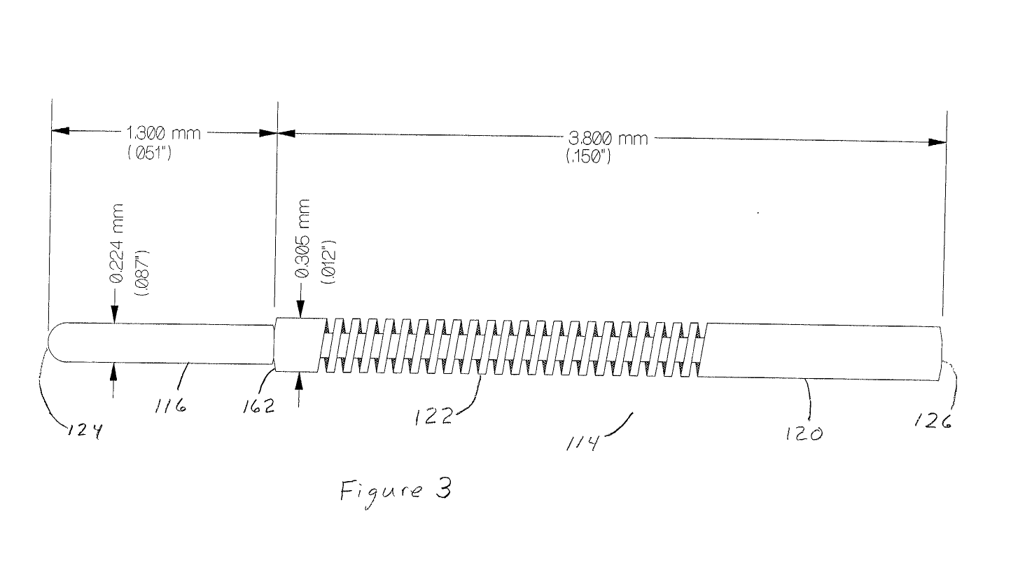

The contacts 114 are elongate, cylindrical, extensible members approximately 0.305 mm in diameter and with a free length of approximately 5.1 mm in this embodiment as shown in FIGS. 1 and 3. The contacts 114 are resiliently compressible along the major axis over approximately 0.7 mm and exert a force of approximately 0.3 Newtons when compressed by 0.3 mm along the major axis. The contacts 114 are commercially available.

The contacts 114 comprise a plunger 116 and a body 120. The plunger 116 of this embodiment is a cylindrical, elongate member approximately 0.224 mm in diameter and is made from gold plated beryllium copper. The body 120 is a hollow, cylindrical member approximately 0.305 mm in outside diameter, 0.23 mm in inside diameter, and of 3.800 mm free length in this embodiment. The body 120 is made of 304 stainless steel coated with nickel and gold. The body 120 further comprises a spring section 122. The spring section 122 is a portion of the body 120 that is cut so as to form a helical spring that is rectangular in cross-section. A first end 162 of the body 120 is fixedly attached to the plunger 116 approximately 1.300 mm from a first end of the plunger 116 in a known manner such that the plunger 116 and the body 120 are coaxial and so that the plunger 116 extends within the spring section 122 of the body 120.

The contact 114 therefore has a plunger end 124 and a body end 126 opposite the plunger end 124. Since the plunger 116 and body 120 are made of electrically conductive materials and are fixedly interconnected, the contacts 114 are materially and electrically continuous from the plunger end 124 to the body end 126. The contacts 114 of this embodiment have an electrical resistance of less than 40 milliohms between the plunger end 124 and the body end 126. Further, the contacts 114, comprising the spring section 122, are compressible over a range of approximately 0.7 mm via the spring section 122 and exert a force of approximately 0.3 Newtons when compressed by 0.3 mm from their free length.

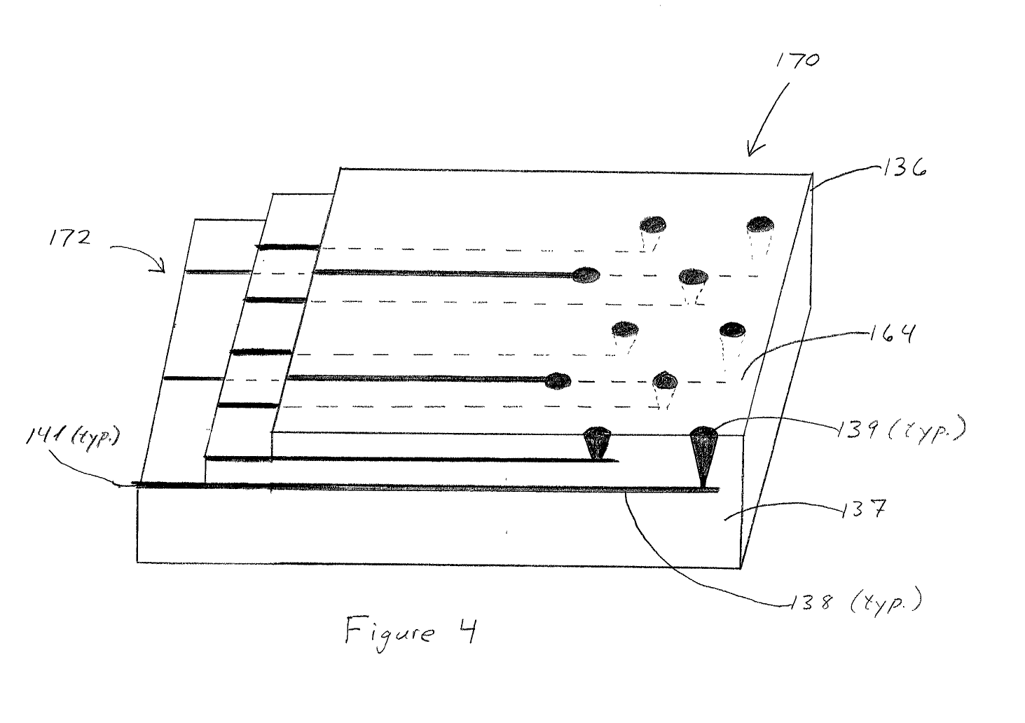

The high density electrical connector 100 also comprises a flex cable 136 as illustrated in FIG. 1 and in section, perspective view in FIG. 4 serving as a lateral expansion structure. The flex cable 136 is a generally planar assembly comprising an electrically insulative material 137 such as polyamide plastic and a plurality of electrically conductive traces 138 formed, for example, from copper extending laterally along the flex cable 136. The electrically conductive traces 138 in this embodiment are exposed in a plurality of first contact regions 139 arrayed in a first contact area 170 on a first face 164 of the flex cable 136. Each first contact region 139 is electrically connected via the corresponding conductive trace 138 to a corresponding second contact region 141 at the opposite end of the corresponding conductive trace 138. The second contact regions 141 are arrayed in a second contact region 172. The first 139 and second 141 contact regions serve as expansion contacts.

As can be seen in FIG. 4, the conductive traces 138 and thus the second contact regions 141 are positioned in a plurality of overlapping layers within the flex cable 136. These overlapping layers are selectively exposed such that the second contact regions 141 are disposed transversely by the plurality of conductive traces 138 as well as longitudinally along the axis of the conductive traces 138 by the selective exposure of the multiple layers of the flex cable 136. Furthermore, the first contact regions 139 are arrayed in a single plane on the first contact area 170 whereas the second contact regions 141 are arrayed in a number of parallel planes on the second contact area 172, the number of parallel planes determined by the number of layers of conductive traces 138 within the flex cable 136. Thus, by varying the construction of the flex cable 136 in alternative embodiments, any given second contact region 141 can be placed in electrical communication with the corresponding first contact region 139 by the corresponding conductive trace 138 wherein the conductive trace 138 can be positioned at any layer within the flex cable 136.

Each conductive trace 138 and corresponding contact region 139, 141 is electrically isolated from other conductive traces 138 and corresponding first 139 and second 141 contact regions by the insulative material 137. Thus, the flex cable 136 permits electrical signals to be independently conducted from each of the first contact regions 139 to each corresponding second contact region 141. In this embodiment, the first contact regions 139 are arrayed in the first contact area 170 with a pitch of approximately 0.25 mm and the second contact regions 141 are arrayed in the second contact area 172 with a pitch of approximately 0.8 mm. Thus, the high density electrical connector 100 provides independent electrical connection between the first contact area 170 of relatively high contact density with the second contact area 172 of relatively low contact density wherein the density of second contact regions 141 in the second contact area 172 can be readily manipulated by varying the placement of conductive traces 138 within the flex cable 136 and by the selective removal of the multiple layers of conductive traces 138 therein.

As shown in FIG. 4, individual conductive traces 138 can overlie/underlie other conductive traces 138. In the embodiment shown in FIG. 4, some of the conductive traces 138 directly overlie/underlie other conductive traces 138, while other conductive traces 138 are positioned in underlying/overlying layers, but do not directly underlie/overlie other conductive traces 138. It will be appreciated that in alternative embodiments, the conductive traces 138 can either all directly underlie/overlie other conductive traces 138 or none of the conductive traces 1388 can overlie/underlie other conductive traces 138. It should be appreciated that the configuration of the flex cable 136 as illustrated in FIG. 4 is simply one example and in other embodiments the conductive traces 138 can extend in a radial, orthogonal, anti-parallel, non-linear, or non-parallel overlapping patterns to meet the needs of a given application and the pattern of the conductive traces 138 as illustrated herein should not be construed as being restrictive of the scope of the invention described herein. In addition, the contact regions 139, 141 of the flex cable 136 may also be located on a second face 166 of the flex cable 136 in alternative embodiments. The flex cable 136 is commercially available.

The high density electrical connector 100 also comprises a chassis 140 (FIG. 1). The chassis is a rectangular piece of rigid material, such as aluminum or plastic. The chassis 140 provides further structural rigidity to the high density electrical connector 100.

The printed circuit board 106, the interposer 110, the flex cable 136, and the chassis 140 are all provided with at least two guide pin holes 142. The guide pins holes 142 are through going circular openings sized so as to closely conform to the guide pins 104. The guide pin holes 142 locate and physically interconnect the printed circuit board 106, the interposer 110, the flex cable 136, and the chassis 140 in a manner that will be described in greater detail below.

The stiffener cover 102 and the printed circuit board 106 are further provided with a plurality of screw holes 144. The screw holes 144 are through going circular openings. The screw holes 144 in the printed circuit board 106 are internally threaded to mate with a plurality of screws 146 in a known manner. The screws 146 of this embodiment are cap screws of a type well known in the art. The stiffener cover 102 is placed adjacent a first face of the printed circuit board 106 such that the guide pins 104 extend through the guide pin holes 142 of the printed circuit board 106, thereby aligning the screw holes 144 of the stiffener cover 102 and the printed circuit board 106. The screws 146 are then placed through the screw holes 144 of the stiffener cover 102 and threaded into the screw holes 144 of the printed circuit board 106 so as to interconnect the stiffener cover 102 and the printed circuit board 106 in a known manner.

A plurality of contacts 114 are placed within the positioning structures 112 within the interposer 110 such that the plunger ends 124 of the contacts 114 are adjacent to and extend outward from the second face 160 of the interposer 110. The first ends 162 of the body 120 of the contacts 114 bear against the steps 134 within the positioning structures 112 thereby supporting the contacts 114 and inhibiting the contacts 114 from passing through the interposer 110. The dimensions of the positioning structures 112 and the contacts 114 are preferably chosen as previously described such that the contacts 114 are free to move axially within the positioning structures 112 yet be inhibited from passing through the interposer 110 by the steps 134. It will be appreciated that inverting the interposer 110 will cause the contacts 114 to fall out. This aspect of the invention facilitates easy insertion and removal of the contacts 114 in the interposer 110.

The dimensions of the positioning structures 112 and the contacts 114 are further preferably chosen so that the contacts 114 extend approximately 0.2 mm beyond the first 156 and second 160 faces of the interposer 110. The first face 156 of the interposer 110 is then placed adjacent the second face 152 of the printed circuit board 106 such that the guide pins 104 pass through the guide pins holes 142 of the interposer 110 thereby securing the interposer 110 to the printed circuit board 106 and the stiffener cover 102 via the guide pins 104 and retaining and compressing the contacts 114 between the steps 134 and the printed circuit board 106.

The first face 164 of the flex cable 136 is placed adjacent the second face 160 of the interposer 110 and the chassis 140 is placed adjacent the second face 166 of the flex cable 136 such that the guide pins 104 pass through the guide pin holes 142 of the flex cable 136 and the chassis 140. The chassis 140 and the stiffener cover 102 are pressed together thereby securing the flex cable 136 and the chassis 140 with the interposer 110 and the stiffener cover 102 via friction fit with the guide pins 104 and compressing the contacts 114 within the positioning structures 112, thereby forming the assembled high density electrical connector 100. The placement of the positioning structures 112 in the interposer 110, the contact pads 154 of the printed circuit board 106, and the contact regions 139 of the flex cable 136 is advantageously chosen such that the assembly of the high density electrical connector 100 in the manner previously described causes the contacts 114 contained within the interposer 110 to establish electrical connection between the circuits of the printed circuit board 106 and the opposite ends 141 of the flex cable 136.

It will be appreciated that the interconnection of the stiffener cover 102, the printed circuit board 106, the interposer 110, the flex cable 136, and the chassis 140 via friction fit with the guide pins 104 is removable. It will also be appreciated that the compressibility and electrical continuity of the contacts 114 contained within the positioning structures 112 of the interposer 110 enable the high density electrical connector 100 to establish electrical connections between the circuits of the printed circuit board 106 and the opposite ends 141 of the flex cable 136 when the high density electrical connector 100 is assembled and to sever electrical connection between the circuits of the printed circuit board 106 and the opposite ends 141 of the flex cable 136 when the high density electrical connector 100 is disassembled. Thus, the circuits of the printed circuit board 106 and the second contact regions 141 of the flex cable 136 can be connected with the high density electrical connector 100 in a non-permanent manner.

It will also be appreciated that the high density electrical connector 100 of overall dimensions of approximately 50 mm by 10 mm by 5 mm and comprising, in this embodiment, up to 360 contacts 114 provides a high contact count in a small dimension connector. In addition, the high density electrical connector 100, by employing the flex cable 136 as herein described facilitates interconnection between regions of relatively high conductor density with regions of relatively lower conductor density.

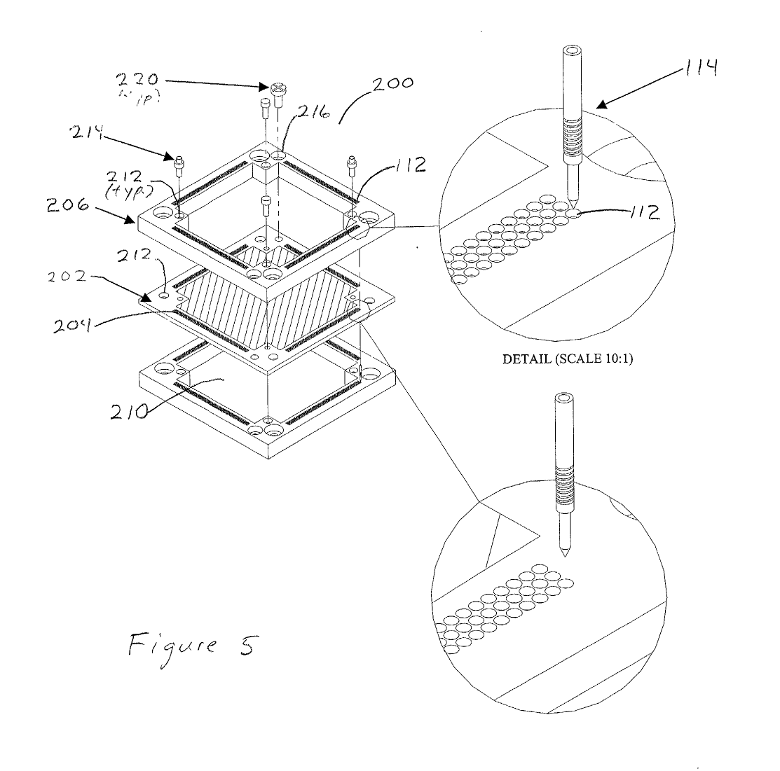

FIG. 5 illustrates a portion of an alternative embodiment of a high density electrical connector 200. The high density electrical connector 200 of this embodiment is suited for use with printed circuit boards 202 wherein discrete devices such as packaged integrated circuits, resistors, and capacitors (not illustrated) are mounted on the surface of the printed circuit board 202 so as to extend above the surface. The high density electrical connector 200 of this embodiment is also suited for vertical interconnection of multiple printed circuit boards 202 in a manner that is tolerant of alternative placement of the printed circuit boards 202 within the high density electrical connector 200 in a manner that will be described in greater detail below.

The printed circuit boards 202 of this embodiment comprise a plurality of contact pads 204 disposed about the periphery of the printed circuit board 202 as illustrated in FIG. 5. The contact pads 204 are exposed regions of the interconnecting vias comprising the printed circuit board 202 and are formed in a known manner. The contact pads 204 preferably extend from one face of the printed circuit board 202 to the opposite face of the printed circuit board 202 so as to facilitate vertical interconnection of the electrical devices mounted on the printed circuit board 202 in a manner that will be described in greater detail below.

The high density electrical connector 200 comprises at least one stackable interposer 206. The stackable interposer 206 is rectangular and is made from electrically nonconductive material. The stackable interposer 206 defines an interior opening 210 that provides clearance for surface mounted devices extending from the surface of the printed circuit board 202.

The stackable interposer 206 also comprises a plurality of positioning structures 112 substantially identical to the positioning structures 112 previously described except that, in this embodiment, the positioning structures 112 are positioned about the periphery of the stackable interposer 206 as illustrated in FIG. 5 so as to be aligned with the placement of the contact pads 204 on the printed circuit board 202. In this embodiment, the high density electrical connector 200 comprises 600 positioning structures 112.

The stackable interposer 206 and printed circuit board 202 also comprise, in this embodiment, four guide pin holes 212. The guide pin holes 212 are cylindrical through-going openings in the stackable interposer 206 and printed circuit board 202. The guide pin holes 212 are sized so as to closely conform to four guide pins 214. The guide pins 214 are rigid, cylindrical elongate members. The guide pins 214 and guide pin holes 212 maintain the printed circuit board 202 and stackable interposers 206 in alignment in a manner that will be described in greater detail below.

The stackable interposer 206 and printed circuit board 202 also comprise, in this embodiment, four screw holes 216. The screw holes 216 are cylindrical, through-going openings in the stackable interposer 206 and printed circuit board 202. The screw holes 216 provide clearance for four screws 220. The screws 220, of this embodiment, are cap screws of a type known in the art. The screws 220 extend through the screw holes 216 and removably interconnect the stackable interposer 206 and the printed circuit board 202 in a manner that will be described in greater detail below.

The high density electrical connector 200 also comprises a plurality of contacts 114. The contacts 114 of this embodiment are substantially identical in form and function to the contacts 114 previously described. In one embodiment, the contacts 114 are placed within positioning structures 112 so as to be adjacent contact pads 204 of the adjacent printed circuit board 202. In an alternative embodiment, contacts 114 are placed in all positioning structures 112. Adjacent layers of printed circuit boards 202 and stackable interposers 206 are brought into contact and positioned such that the guide pin holes 212 of the printed circuit boards 202 and the stackable interposers 206 are aligned. The guide pins 214 are then pressed through the guide pin holes 212 in the printed circuit boards 202 and the stackable interposers 206 to maintain the printed circuit boards 202 and the stackable interposers 206 in alignment. The screws 220 are then placed through the screw holes 216 and secured in a known manner to secure the printed circuit boards 202 and the stackable interposers 206 together in compression and compress the contacts 114 contained within the positioning structures 112 of the stackable interposers 206.

It will be appreciated that the high density electrical connector 200 as herein described can be readily extended to include additional layers of printed circuit boards 202 and stackable interposers 206 beyond the single layer illustrated in FIG. 5. In one alternative embodiment, all of the positioning structures 112 are filled with contacts 114. In this embodiment, the contacts 114 contact and are therefore electrically continuous with the corresponding contacts 114 above and below in other stackable interposers 206. In this embodiment, printed circuit boards 202 can be placed at any layer within the high density electrical connector 200 and, since contacts 114 are placed in all of the positioning structures 112 and are vertically electrically continuous, contact will be made with the printed circuit boards 202 regardless of the position within the stack in which the printed circuit boards 202 are placed. Thus, the high density electrical connector 200 of this embodiment, is tolerant of alternative placement of the printed circuit boards 202 within the high density electrical connector 200.

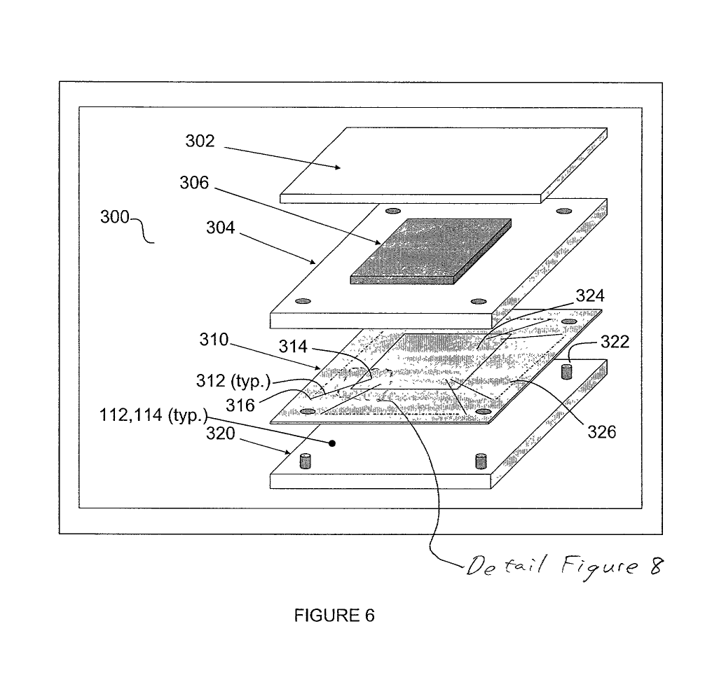

FIG. 6 is an exploded, perspective view of an alternative embodiment of a high density electrical connector 300. The high density electrical connector 300 interconnects an area of relatively high contact density with an area of relatively low contact density in a similar manner to that previously described for the high density electrical connector 100 as shown in FIGS. 1 and 4.

The high density electrical connector 300 comprises a heat sink 302. The heat sink 302 is a generally planar and rectangular member made of material with good heat transfer and capacity characteristics, such as aluminum. The heat sink 302 is adapted to be fastened adjacent a printed circuit board 306 and to transfer heat therefrom in a well understood manner. The printed circuit board 306 includes a plurality of electrical components and generates and processes electrical signals in a well known manner. The printed circuit board 306 also includes a plurality of surface mounted contacts that are obscured from view in FIG. 6.

The printed circuit board 306 is positioned adjacent a first interposer 304 such that the surface mount contacts of the printed circuit board 306 are adjacent the first interposer 304. The first interposer 304 also comprises a plurality of positioning structures 112 with contacts 114 positioned therein substantially identical to that previously described with respect to the high density electrical connector 100, 200. The positioning structures 112 and the contacts 114 are positioned within the first interposer 304 such that the contacts 114 contact the surface mount contacts of the printed circuit board 306.

The high density electrical connector 300 also comprises a flex cable 310. The flex cable 310 of this embodiment is made of substantially the same materials as those previously described with respect to the flex cable 136. The flex cable 310 includes a plurality of conductive traces 312 with first contact regions 314 disposed in a first contact area 324 and with second contact regions 316 disposed in a second contact area 326. The conductive traces 312 of this embodiment are substantially similar to the conductive traces 138 previously described except that the conductive traces 312 are arranged in a generally radial pattern. As the total number of conductive traces 312 and first contact regions 314 in preferred embodiments is in excess of 1000, FIG. 6 schematically illustrates the general orientation of the conductive traces 312, but does not show all of the conductive traces 213 or the first contact regions 314.

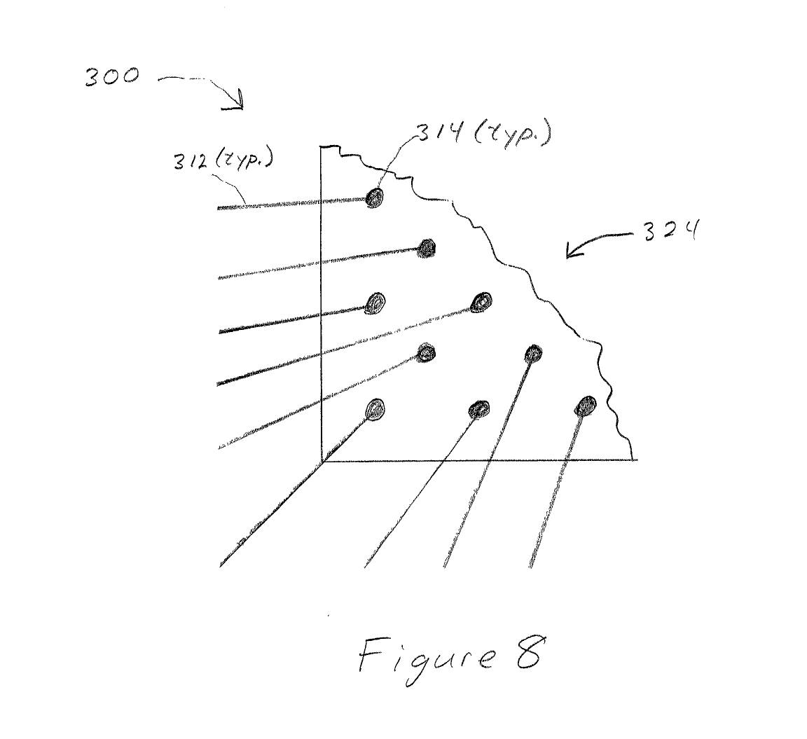

FIG. 8 is a top, detail view of a portion of one embodiment of the conductive traces 312 and the first contact regions 314 in the first contact area 324. It will be appreciated that the exact placement and routing of the full number of conductive traces 312 will vary depending on the particular implementation.

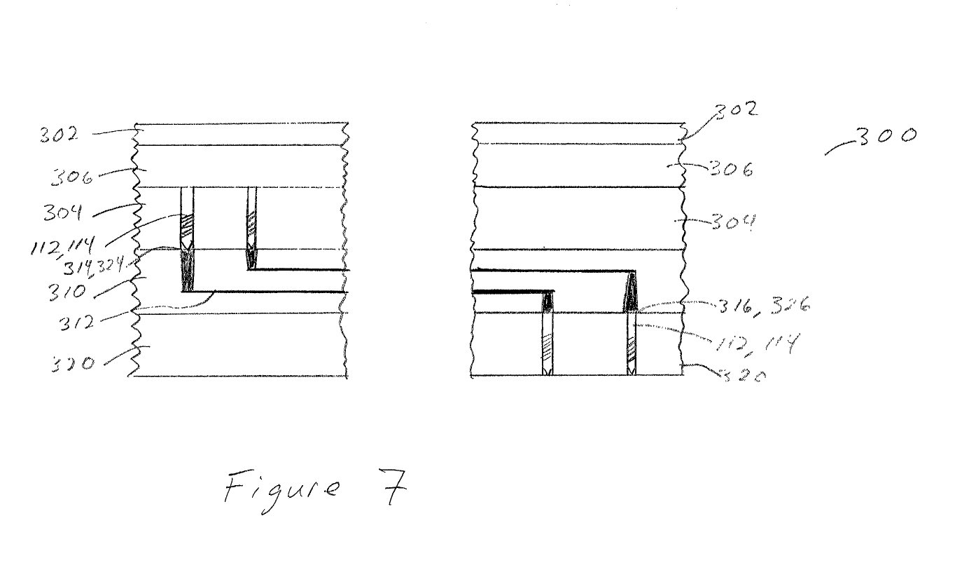

The first contact regions 314 are positioned so as to contact the contacts 114 extending through the first interposer 304 and thus be in electrical communication with the circuits of the printed circuit board 306. The second contact regions 316 are positioned on the opposite side of the flex cable 310 from the first contact regions 314 as shown in FIG. 7. The radial arrangement of the conductive traces 312 facilitates positioning the second contact regions 316 in a lower density second contact area 326 as compared to the relatively dense arrangement of the first contact regions 314 in the first contact region 324. In this embodiment, the first contact regions 314 are arranged in the first contact area 324 with a pitch of approximately 0.5 mm-1.25 mm and the second contact regions 316 are arranged in the second contact area 326 with a pitch of approximately 2 mm. It should also be appreciated that FIG. 7 is a schematic illustration of certain aspects of the invention and is not to scale.

The high density electrical connector 300 also comprises a second interposer 320 having a plurality of positioning structures 112 and contacts 114 positioned therein. The positioning structures 112 and the contacts are positioned so as to be adjacent the second contact regions 316 of the flex cable 310. The second interposer 320 also includes a plurality of guide pins 322 extending generally perpendicular from the surface of the second interposer 320 adjacent the flex cable 310. The guide pins 322 mechanically interconnect the second interposer 320, the flex cable 310, the first interposer 304, and the heat sink 302 in a well understood manner.

The contacts 114 in the second interposer 320 extend through the positioning structures 112 therein so as to extend beyond the surface of the second interposer 320 and facilitate connection to further circuits not shown. While this embodiment has shown two interposers 304, 320, in alternative embodiments additional interposer can be provided to interconnect the printed circuit board 306 in alternative arrangements.

Although the foregoing description of the preferred embodiment of the present invention has shown, described, and pointed out the fundamental novel features of the invention, it will be understood that various omissions, substitutions, and changes in the form of the detail of the apparatus as illustrated as well as the uses thereof, may be made by those skilled in the art without departing from the spirit of the present invention. Consequently, the scope of the present invention should not be limited to the foregoing discussions, but should be defined by the appended claims.

What is claimed is:

1. A device for interconnecting a first electrical device having a plurality of contacts disposed on a first surface in a first pattern at a first density to a second electrical device having a plurality of contacts disposed on a second surface in a second pattern at a second density, wherein the second density is less than the first density, the device comprising:
a first contact support structure that includes a plurality of contact members each having a first and a second end wherein the plurality of contact members are arranged in the first pattern such that when the contact support structure is positioned adjacent the first surface of the first electrical device, the first end of the plurality of the contact members are electrically coupled to the first plurality of contacts; and
a lateral expansion structure having a plurality of laterally extending traces each having a first and a second expansion contact arranged at first and second ends of the laterally extending traces respectively wherein the first expansion contacts are coupled to the second ends of the plurality of contact members and wherein the second expansion contacts are arranged so as to be coupled to the plurality of contacts on the second electrical device.

2. The device of claim 1, further comprising a securing mechanism that removably secures the first and second electrical devices, the contact support structure and the lateral expansion structure together.

3. The device of claim 1, wherein the first electrical device comprises a packaged integrated circuit and the second electrical device comprises a printed circuit board.

4. The device of claim 1, wherein the contact support structure comprises a planar member having a plurality of openings formed therein and wherein the plurality of contacts members comprise a plurality of compressible contacts positioned within the openings such that the first and second ends of the contact members protrude therefrom so as to make electrical contact with the plurality of contacts of the first electrical device and the first expansion contacts of the laterally extending traces of the lateral expansion structure respectively.

5. The device of claim 1, wherein the lateral expansion structure comprises a flex cable having a first area upon which the first plurality of expansion contacts are disposed and a second area upon which the second plurality of expansion contacts are disposed and wherein the flex cable includes an interposed region between the first and second surfaces where the plurality of laterally extending traces are disposed.

6. The device of claim 1, further comprising a second contact support structure that includes a plurality of contact members each having a first and a second end wherein the plurality of contact members are arranged in the second pattern wherein the second contact support structure is interposed between the lateral expansion structure and the second electrical device such that the first end of the plurality of the contact members are electrically coupled to the second expansion contacts and the second ends of the contact members are electrically coupled to the second device.

7. The device of claim 1, wherein the first pattern comprises a spacing pitch of no more than 0.25 mm and the second pattern comprises a spacing pitch of at least 0.75 mm.

8. The device of claim 1, wherein the second pattern has a pitch of at least three times the pitch of the first pattern.

9. A device for interconnecting a first contact pattern of a first density to a second contact pattern of a second density, the device comprising:
a contact structure having a plurality of contact members each having a first end and a second end wherein the first ends of the plurality of contact members electrically couple to the first contact pattern and wherein the plurality of contact members extend in a first direction that intersects the first surface such that the second ends of the plurality of contact members are spaced from the first plurality of contacts in the first direction;
an expansion structure that has a first plurality of expansion contacts that electrically couple to the second ends of the plurality of contact members when the expansion structure is mounted to the contact structure, wherein the expansion structure further includes a plurality of laterally extending conductors each having a first end that is electrically coupled to the first plurality of expansion contacts wherein the laterally extending conductors extend in a second direction that intersects the first direction and wherein the lateral expansion structure further includes a plurality of second expansion contacts that are coupled to the second ends of the laterally extending conductors such that the plurality of second expansion contacts device the second contact pattern at a second density that is laterally spaced outward from the first contact pattern.

10. A device for removably interconnecting electrical devices comprising:
a plurality of resiliently compressible contacts;
an interposer containing the plurality of contacts wherein the contacts extend from a first face of the interposer to a second face of the interposer opposite the first face of the interposer;
a first electrical circuit having a plurality of circuit nodes, each node in electrical contact with one end of one of the contacts; and
a flex cable comprising a plurality of laterally extending electrically conductive traces wherein one end of the electrically conductive traces is in electrical contact with a second end of the contacts and wherein the flex cable provides a region of relative high conductor density at one end of the electrically conductive traces and a corresponding region of relative low conductor density at a second end of the electrically conductive traces.

11. The device of claim 10, wherein the conductive traces of the flex cable extend in a parallel arrangement.

12. A device for vertically interconnecting electrical components comprising:
a plurality of compressible contacts;
an interposer containing the plurality of contacts wherein the contacts extend from a first face of the interposer to a second face of the interposer opposite the first face of the interposer; and
an electrical device containing a plurality of electrical circuit components in electrical contact with one end of the contacts.

13. The device of claim 12 comprising alternating layers of a plurality of interposers each containing a plurality of contacts and a plurality of electrical devices positioned in alignment with the interposers.

14. The device of claim 13, wherein corresponding contacts contained within the interposers are electrically continuous throughout the vertical extent of the device.
